(19) United States
(12) Patent Application Publication
(10) Pub. No.: US 2017/0309565 A1
(43) Pub. Date: Oct. 26, 2017

(54) METHOD OF MANUFACTURING SEMICONDUCTOR DEVICES

(71) Applicant: Infineon Technologies AG, Neubiberg (DE)

(72) Inventors: Joerg Ortner, Drobollach (AT); John Cooper, Villach (AT)

(73) Assignee: Infineon Technologies AG, Neubiberg (DE)

(21) Appl. No.: 15/137,431

(22) Filed: Apr. 25, 2016

(51) Int. Cl. H01L 23/525

(52) U.S. Cl. CPC H01L 23/5256

(57) ABSTRACT

A method for use in manufacturing semiconductor devices includes providing a structured layer on a wafer, and selectively providing a substance on a selected portion of the structured layer. A die comprises a semiconductor device on a substrate, where the semiconductor device includes a substance, and where the substance has a sidewall that is sheer with respect to one or more of a base surface or a top surface of the substrate.

The present application relates to a method of manufacturing semiconductor devices.

### BACKGROUND

Photolithography is a process used in microfabrication to pattern parts of a thin film or a substrate. Photolithography uses light to transfer a geometric pattern from a photomask to a light-sensitive chemical photoresist on the substrate. A series of chemical treatments then either engraves the exposure pattern into, or enables deposition of a new material into a desired pattern.

In recent years inkjet printing has been used in the manufacturing of semiconductor devices. Inkjet printing can be controlled to selectively deliver a substance to be deposited on one or more selected portions of the wafer. Thus, a great deal of flexibility is achieved when inkjet printing is used in the manufacturing of semiconductor devices. However, it is desirable to improve the accuracy of inkjet printing techniques.

### SUMMARY

According to an embodiment of a method, the method includes providing a structured layer on a wafer, and selectively providing a substance on a selected portion of the structured layer.

According to an embodiment of a die, the die includes a semiconductor device on a substrate and the semiconductor device includes a substance. The substance has a sidewall that is sheer with respect to one or more of a base surface or a top surface of the substrate.

### BRIEF DESCRIPTION OF THE DRAWINGS

Objects and features of the techniques disclosed herein will become apparent from the following description of exemplary embodiments and exemplary embodiments with reference to the following figures, wherein like reference numerals refer to like parts throughout the various figures unless otherwise specified.

FIG. 1 illustrates an embodiment of a method.

FIGS. 2A-2E illustrate cross-sectional views of an embodiment of a method of forming a substrate.

FIGS. 3A-3E illustrate cross-sectional views of an embodiment of a method of forming a substrate.

FIGS. 4A-4E illustrate cross-sectional views of an embodiment of a method of forming a substrate.

The illustrated structures and/or devices are not necessarily drawn to scale.

### DETAILED DESCRIPTION

Below, embodiments, implementations and associated effects are disclosed with reference to the accompanying drawings. As used herein, like terms refer to like elements throughout the description.

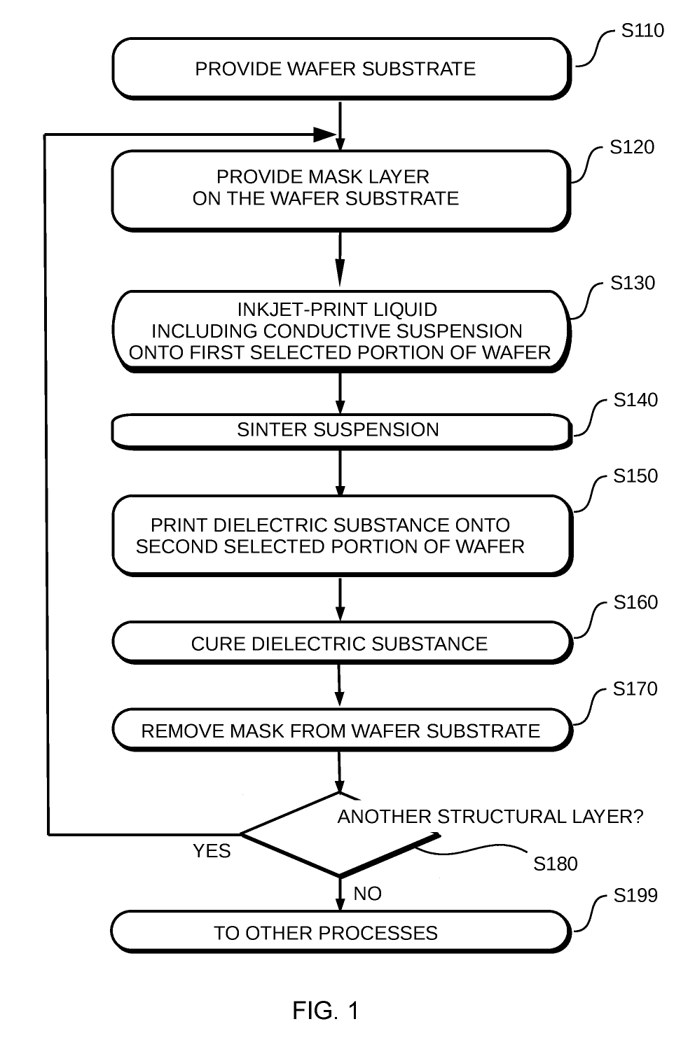

FIG. 1 is a diagram that schematically illustrates a flowchart of a method according to some embodiments. The method can be used in manufacturing semiconductor device chips. In some embodiments, a plurality of semiconductor device structures provided on a wafer substrate forms a portion of a corresponding plurality of integrated circuits to be manufactured based on the wafer substrate. For example, the semiconductor device chips can comprise each one or more integrated circuits. In some embodiments, the semiconductor device includes a power transistor. In some embodiments the semiconductor device includes a micro-electrical-mechanical element or micro-electrical-mechanical system (MEMS). For example, the semiconductor device can include a mechanical sensor element such as a pressure sensor element. In some embodiments at least two of the afore-mentioned elements are combined in the semiconductor device chip.

In the illustrated embodiment, the method includes providing a structured layer on a wafer and selectively providing a substance on a selected portion of the structured layer. Thus, a method to selectively deliver a substance at a selected portion of the wafer such as an inkjet technique, a micro-aerosol printing technique or a micro-extrusion printing technique can be implemented in a manufacturing process of a semiconductor device. In the illustrated embodiments, the printing is assisted by the structured layer in that, during the printing process, the structured layer functions as a mask layer, and is sometimes also referred to as an auxiliary mask, with respect to the substance delivered when using the inkjet technique. In the illustrated embodiments, an improved precision of selected delivery of the substance onto the substrate can be achieved when compared with techniques that utilize inkjet printing without using the auxiliary mask. In the illustrated embodiments, greater precision is achieved by utilizing a mask that is provided on a substrate as compared to using droplets from an inkjet printer. In some implementations, the method further includes removing the structured layer from the wafer substrate. In some embodiments, the substance is one selected from a group that includes a liquid, a suspension in a liquid, and a paste.

Now, with reference to FIG. 1, at S110, the method includes providing a wafer that, in one embodiment, includes a plurality of semiconductor device structures. In some embodiments, semiconductor device structures form a portion of an integrated circuit. The semiconductor device structures can be configured to form passive circuit elements such as resistors, inductors and capacitors. Further, the semiconductor device structures can be configured to form active circuit elements such as transistors. The skilled person will understand that, where the semiconductor device structure is provided to form an integrated circuit, a large number of passive circuit elements and active circuit elements can be included in a single semiconductor device structure. In one embodiment, the semiconductor device structure is included within a sensor chip product. The wafer can generally be provided for front-end processing as known in the art.

At S120, the method includes providing a mask layer on the wafer substrate. In some embodiments, the mask layer is provided using a photolithography technique. For example, the mask can be provided as a positive resist mask or as a negative resist mask. Other embodiments include an oxide hard mask. In still other embodiments, the mask layer is provided as a nitride mask. The mask layer can be structured. For example, the mask can be provided with openings adapted to receive a substance in further process steps such as to receive an ink in the course of an inkjet printing step that is performed to selectively implant the ink in at least one selected opening.

In some embodiments, the substance is provided as an ink or the substance otherwise forms part of an ink. As used herein, the wording “ink” means a substance adapted for use with inkjet techniques for delivery of the substance to the substrate. By using a controllable inkjet printer, the inkjet printing can be performed selectively. For example, at S130, the method includes inkjet printing liquid onto a first selected portion of the wafer. In some embodiments, the liquid includes a suspension. In some embodiments, the suspension is conductive. For example, by using a controllable inkjet printer, the inkjet printing can be performed selectively. At least one benefit that is achieved is that the liquid can be deposited on the substrate in accordance with control of the inkjet printer. In some embodiments, the inkjet printer is controlled to perform steps such as moving a nozzle configured to dispense the liquid and a support for the substrate with respect to one another such that a predetermined pattern and/or distribution of liquid is formed on the substrate. Generally, in some embodiments, the substance is at least one selected from the group consisting, at the time of the act of providing the substance, of a liquid, a suspension in a liquid and a paste. In some embodiments, the substance includes a metal.

In some embodiments, the method further includes using the substance to complement a circuit element structure at the selected portion of the wafer. In some embodiments, the wafer includes a plurality of semiconductor device structures, and the circuit element structure forms part of a semiconductor device structure. For example, in some embodiments, the pattern can be a fuse bank pattern that includes a plurality of fuses, for example, arranged side by side. In some embodiments, the circuit element structure forms part of a wafer test circuit structure. Accordingly, the control of, for example, the inkjet printer can be based on a result of a measurement performed on the wafer. For example, where in respect of a conductor path a measured resistance value was measured, the inkjet printer can be controlled so as to add conductive liquid to form conductive elements configured to broaden the conductor path so as to reduce the path resistance down to a predetermined resistance value that is below the measured resistance value. In some embodiments, the act of selectively providing the substance on the selected portion of the wafer digitally encodes information on the wafer. For example, by selectively setting conductive elements in a fuse bank, a digital representation of a value can be encoded for the semiconductor device that is associated with the fuse bank.

Generally, the method can further include hardening the substance. For example, at S140, the method includes hardening the liquid. The hardening can include evaporating a solvent from the liquid. In some embodiments, the method further includes sintering the substance. For example, where the liquid includes a suspension, the hardening can include sintering the suspension. It should be understood that sintering is only one example of hardening the suspension. Further, in some embodiments, a dedicated process step of hardening the liquid may not be needed.

In some embodiments, the substance is adapted to passivate a circuit element at the selected portion of the substrate. For example, at S150, the exemplary method includes inkjet printing a second liquid onto the wafer. The second liquid can include a resin. In some embodiments, the resin includes a dielectric resin. In some embodiments, the dielectric resin is printed onto a second selected portion of the wafer.

At S160, the method includes hardening the liquid. For example, the hardening can include evaporating a solvent from the liquid. In some embodiments, the act of hardening the substance includes curing the substance or cross-linking the substance. For example, where the liquid includes a resin, the hardening can include curing the resin. Further, in some embodiments, a dedicated process step of hardening the liquid may not be needed.

At S170, the method includes removing mask material. In some embodiments, the mask material is completely removed from the substrate. In some embodiments, for example, where the mask is a hard mask, removing mask material can be limited to removing excessive mask material. For example, in some embodiments, chemical mechanical polishing is performed on the mask in order to remove mask material. At least one effect can be that, in the process of removing mask material, substance printed atop the mask material also gets removed.

At S180, it is determined, if another layer of material should be added atop the previously manufactured layer. If so, the method can further include one or more steps as those described above. In particular, a flow of the method or a portion of the method described above can be repeated in order to selectively add further conductive and/or dielectric elements on the wafer by way of inkjet printing wherein a mask layer can be used in accordance with the techniques disclosed herein. If not, at S199, the method can move on to perform other front-end or back-end processes.

Generally, in an embodiment, a die includes a semiconductor device on a substrate. In some embodiments the substrate is planar. In some embodiments, the substrate has a non-planar topology, for example, due to semiconductor device structures that were formed during preceding manufacturing steps. The semiconductor device includes a substance having a sidewall. More particular, the substance can form an element, a component or a structural feature of the semiconductor device. The sidewall is essentially sheer with respect to a base surface and/or to a top surface of the substrate. At least one effect can be that the sidewall is seen essentially without curvature when looking from a foot of the sidewall along the sidewall upwards to a top of the sidewall. In some embodiments, as a result of an undercut in the resist mask, the sidewall can include a protruding portion or nose portion. Owing to the ability to manufacture a structural layer as an auxiliary mask for use in printing the substance on the substrate, wherein a structure of the structural layer has sheer sidewalls, the substance with the sheer sidewall can be manufactured using the techniques described herein. In some embodiments, the substance on the selected portion of the wafer is conductive and configures an element of the semiconductor device. In some embodiments, the element is a constructive fuse element. In some embodiments, the semiconductor device includes a plurality of fuse elements arranged in a fuse bank including the constructive fuse element. In some embodiments, the conductive substance is covered by a dielectric substance. Exemplary embodiments will now be described with reference to cross-sectional views shown in the drawings.

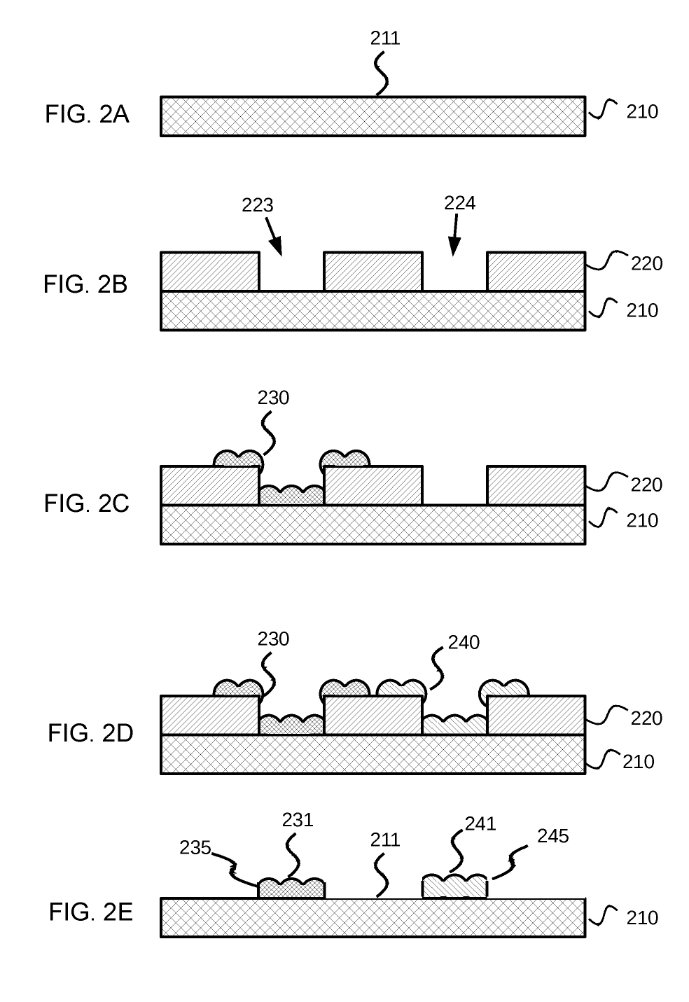

FIGS. 2A-2E illustrate cross-sectional views of an embodiment of a method of forming a substrate. Now, with reference to FIG. 2A, a wafer or other substrate 210 is provided. The substrate can have a planar surface 211. In some embodiments (not shown in the figures), the substrate has a topology other than planar. For example, the substrate can be a half-finished product that includes a base substrate with a semiconductor device structure manufactured thereon that provides topology to the substrate. In such a case the surface of the substrate used in process steps described herein can be non-planar.

Next, as shown in FIG. 2B and as described above with reference to embodiments of the method illustrated by way of the flowchart in FIG. 1, an auxiliary mask provided with a mask layer 220 that is formed on the substrate 210. The mask layer 220 is structured. For example, the mask layer 220 can include mask trenches and/or mask holes, sometimes also referred to as mask vias. To give an example, FIG. 2B schematically illustrates a first cross-section of a first mask hole 223. Further, to give another example, FIG. 2B illustrates a second cross-section which is a cross-section of a second mask hole 224. In the example of FIG. 2B, it should be understood that the cross-section can also depict a mask trench wherein the mask trench runs into and out of a plane with the cross-section of the cross-sectional view; for example, the mask trench can run perpendicular to the plane.

FIG. 2C schematically illustrates the substrate 210 with the mask layer 220 and co-located droplets of a first substance 230 that are deposited in the first mask hole 223 and, possibly due to an acceptable lack of precision of the printing device used to dispense the first substance 230, also in the immediate vicinity of the first mask hole 223, i.e., on shoulders of the mask layer 220 adjacent to the first mask hole 223. In some embodiments, the first substance 230 is liquid. In some embodiments, the liquid is inkjet-able, i.e., the liquid is adapted for use with an inkjet printing device. The first substance 230 can also be a suspension included in a liquid. At least one effect of using the mask in accordance with the present example can be that capillary forces can provide for the first substance 230 to be virtually sucked into the first mask hole 223 even if the placement of the first substance 230 should not be precisely on top of the first mask hole 223. In some embodiments, the suspension includes a conductive material such as a metal. In some embodiments, the first substance 230 is a paste. In some embodiments, the paste is adapted for use with an extruder device configured to selectively dispense or otherwise deliver the paste to a selected portion of the substrate 210.

FIG. 2D schematically illustrates the substrate 210 with the mask layer 220 and with droplets of a second substance 240 deposited in the second mask hole 224 and immediate vicinity of the second mask hole 224, i.e., on a rim of the mask layer 220 surrounding to the hole 224. It should be understood that the embodiment illustrated in FIG. 2D is optional and merely an example to show that the method can include multiple steps of selectively providing a substance on the substrate 210, and, in particular, the method can include multiple steps of implanting substances in openings of the mask layer 220. In the example shown in FIG. 2D, having regard to the second substance 240, it can be the same as the first substance 230. The second substance 240 can also differ from the first substance 230. Like the first substance 230, in some embodiments, the second substance 240 can be liquid. In some embodiments, the liquid is adapted for use with an inkjet printing device. In some embodiments, the second substance 240 is a suspension included in a liquid. In some embodiments, the suspension is a conductive material such as a metal. In some embodiments, the second substance 240 is a paste. In some embodiments, the paste is adapted for use with an extruder device. For example, the paste is a dielectric. In some embodiments, the second substance is selectively applied on top of the first substance 230 (not shown in FIG. 2D). For example, where the first substance is conductive, the second substance can be a dielectric that isolates a portion of the conductive first substance from other conductors on the substrate 210 to the extent that the conductive first substance is covered by the dielectric second substance.

FIG. 2E schematically illustrates the substrate 210 after removal of the mask layer 220. The first substance 230 is left standing to form a first structural element 231. The first substance 230 is solid. Owing to a sheer sidewall of the holes in the mask layer, the first structural element 231 has, with respect to the essentially planar surface 211 of the substrate 210, a sheer wall 235. Likewise, the second substance 240 is left standing to form a second structural element 241. The second substance 240 is solid and also has, with respect to the essentially planar surface 211 of the substrate 210, a sheer wall 245.

It should be understood that the above described embodiments, methods and techniques can be followed by further processing steps. For example, further layers of material can be deposited on the substrate with the first structural element 231 and the second structural element 241 such that, in a finished product, for example in a die including the semiconductor device, the sheer wall 235 of the first structural element 231 and/or the sheer wall 245 of the second structural element 241 need not face air. The first structural element 231 and/or the second structural element 241 can be buried underneath and/or encapsulated by material that was deposited on the substrate after the above-described steps were performed. The first structural element 231 and/or the second structural element 241 can be in an active region of the wafer, for example, to form part of an electrical element of the semiconductor device. In some embodiments, the first structural element 231 and/or the second structural element 241 are formed outside any active region of the wafer, for example, to be used in wafer testing and, in some embodiments, where formed in a kerf region, to be lost in subsequent dicing of the wafer.

Using the above-described techniques to manufacture a sandwich structure of a metal layer, in particular since the auxiliary mask allows printing with a high level of precision, for example, a precise capacitive element can be manufactured as required according to detection during manufacturing. For example, inside the opening in the auxiliary mask layer, a sandwich capacitive circuit element can be formed that includes a dielectric substance layer and another metal layer. A capacitance value of the precise capacitive element can be controlled by adjusting, in the process of printing the precise capacitive element, the thickness of the dielectric layer and/or by selecting the dielectric substance from a variety of dielectric substances with different dielectric constants so as to achieve the desired capacitance value.

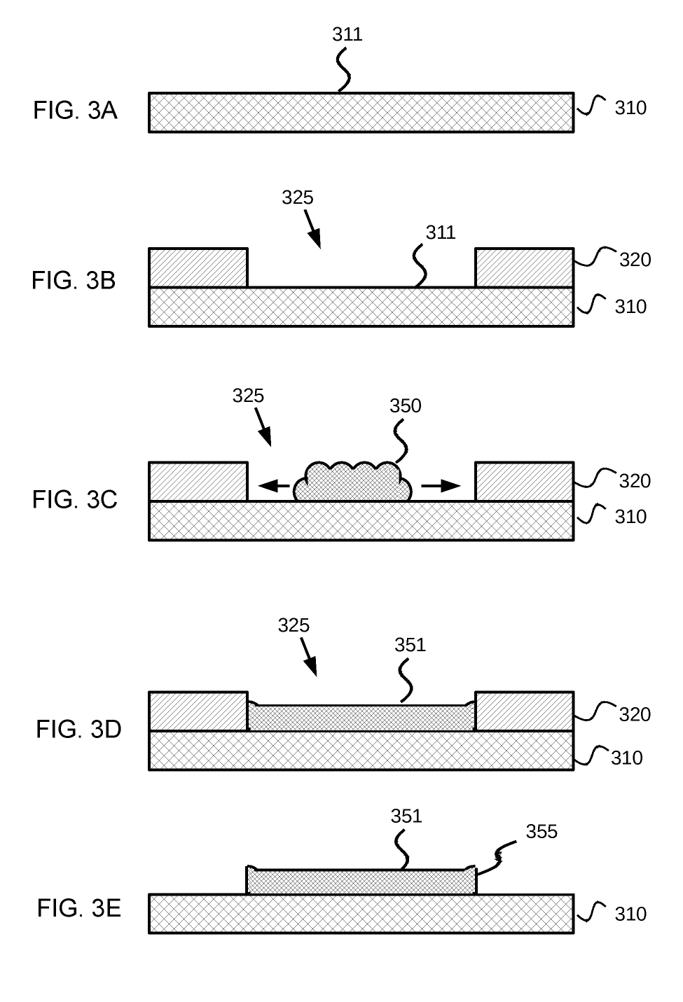

FIGS. 3A-3E illustrate cross-sectional views of an embodiment of a method of forming a substrate. Now, with reference to FIG. 3A, a wafer or other substrate 310 is provided. The substrate can have a planar surface 311.

As schematically shown in FIG. 3B and as described above with reference to embodiments of the method illustrated by way of the flowchart in FIG. 1, a mask layer 320 is supplied on the substrate 310. The mask layer 320 is structured. For example, the mask layer 320 can include a mask basin 325. To give one example, FIG. 3B illustrates a cross-section of the mask basin 325. As will become apparent shortly, in the example of FIG. 3B, the mask basin 325 is wider than a droplet of a substance to be provided in the basin by using the techniques described herein, in particular with reference to FIG. 1. In the example illustrated in FIG. 3B, a floor of the basin 325 is formed by the surface 311 of the substrate 310.

Further, now with reference to FIG. 3C, a few droplets of a substance 350 are deposited in the basin 325. As described above with reference to FIG. 1, in some embodiments, the substance 350 is liquid. In particular, in some embodiments the substance 350 is inkjet-able, and an inkjet printer can be used to selectively dispense the substance 350 into the mask basin 325. In some embodiments, the substance 350 is a paste that is selectively extruded or otherwise dispensed and delivered to the mask basin 325. Compared with a minimum amount of the substance 350 that can be controlled to be selectively deposited in the mask basin 325, the capacity of the mask basin 325 is larger. Thus, as shown in FIG. 3C, the substance 350 provided in the mask basin 325 does not completely fill the mask basin to the limit of its capacity. Where the viscosity of the substance 350 set down in the mask basin 325 is low when compared with the surface tension of the substance 350, the substance 350 flows sideways to cover most or all of the floor of the mask basin 325 (as indicated in FIG. 3C by horizontal arrows). In some embodiments, flow of the substance 350 inside the mask basin 325 is enhanced by decreasing a resistance of the substance 350 to deformation, i.e., be decreasing the viscosity of the substance 350. For example, heating the substance 350 can decrease the substance's viscosity. Heating can be provided selectively, for example, by selectively directing radiation to the location of the mask basin 325. In some embodiments, a further process step, inserted into the flow of process steps after the substance 350 has been selectively deposited at one or more selected locations on the wafer, is performed, wherein the wafer is globally heated and/or the surface of the wafer is globally exposed to heat radiation so as to increase the viscosity of the substance 350.

FIG. 3D schematically illustrates the substrate 310 provided with the mask basin 325 formed in the mask layer 320, wherein, as a result of the flow of the substance 350 inside the mask basin 325, the floor of the mask basin 325 is, for example, completely covered by the substance 350. In some embodiments, in particular where a hardening step is performed as described above with reference to FIG. 1, the substance 350, when hardened, forms a structural element 351 of the device to be manufactured.

FIG. 3E schematically illustrates the substrate 310 after removal of the mask layer from the substrate 310. The structural element 351 is provided atop the substrate 310. The structural element 351 has an essentially sheer wall 355.

At least one advantage of the techniques disclosed herein is that by selecting the right material for the substance 350, by adjusting process steps, determining a suitable volume and/or shape of the mask basin 325, selecting a volume of substance 350 delivered to the mask basin 325, etc., characteristics and properties of the structural element 351 formed in the mask basin 325 can be controlled to meet requirements regarding electrical, magnetic and/or mechanical requirements. Since the printing process can be controlled, for example based on measurement results obtained during processing, the printing process can be adjusted to obtain the structural element with desired properties. In some embodiments, the substance is an etch substance adapted to etch underlying material of the substrate.

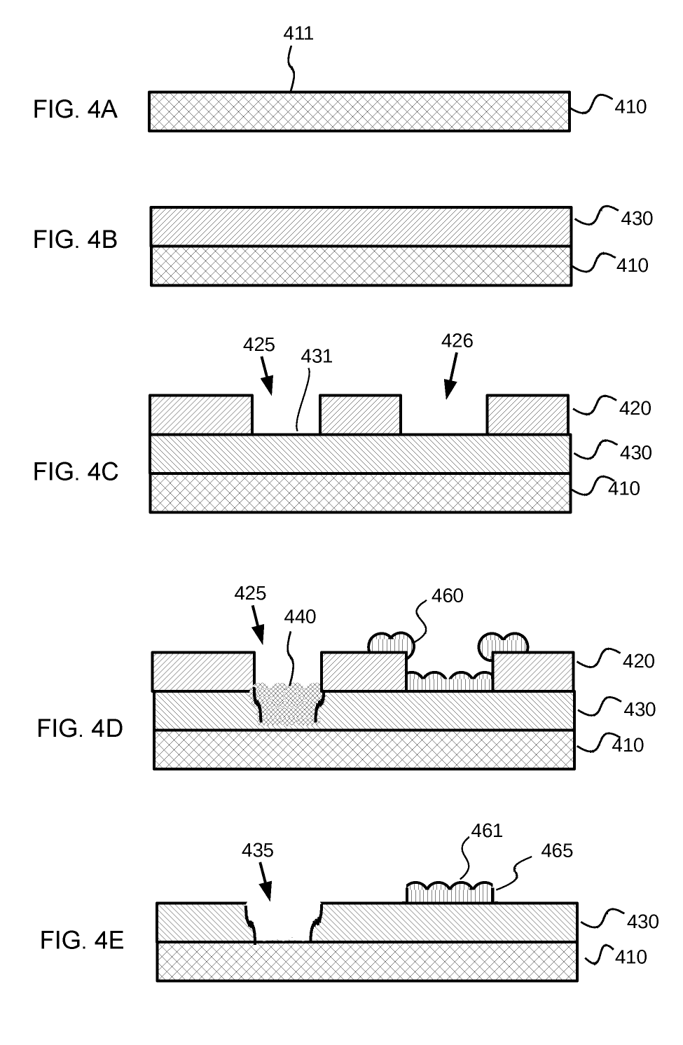

FIGS. 4A-4E illustrate cross-sectional views of an embodiment of a method of forming a substrate. In various embodiments, the method illustrated in FIGS. 4A-4E is similar to those described above except that the substance is provided as an etchant having a destructive effect.

FIG. 4A schematically illustrates a wafer or other substrate 410. The substrate 410 can have a planar surface 411.

FIG. 4B schematically illustrates the substrate 410 with a substrate layer 430 added thereon. In some embodiments, the substrate layer 430 is, for example, a metal layer.

FIG. 4C schematically illustrates a mask layer 420 being supplied on the substrate layer 430. The mask layer 420 is structured. For example, as shown in FIG. 4C, the mask layer 420 can be provided with a first opening 425 configured to receive a selectively delivered substance. The first opening 425 in the mask layer 420 is thus configured to guide the substance onto a portion of the surface of the substrate layer 430 that is exposed to the first opening 425. Similarly, the mask layer 420 can include a second opening 426.

FIG. 4D schematically illustrates a substance 440 selectively delivered to the first opening 425 in the mask layer 420. In some embodiments, an inkjet printing technique as described above is used to dispense the substance 440. The substance 440 can be an etchant, for example a liquid etchant, that etches, as schematically illustrated in FIG. 4D, the material of the underlying substrate layer 430. At least one advantage is that the first opening 425 in the mask layer 420 can guide the etchant onto a surface of the substrate layer 430, whereby a location of the etchant can be precisely selected. Further, FIG. 4D schematically illustrates a second substance 460 being selectively delivered to the second opening 426 in the mask layer 420 as, for example, described above with reference to FIG. 2D.

FIG. 4E schematically illustrates the substrate 410 including the substrate layer 430 after removal of the mask layer 420 and after removal of the substance 440. As a result of the etching effect of the substance 440, the substrate layer 430 includes an opening 435. For example, where the substrate layer 430 is formed as an electrical line, the opening 435, in effect, can disrupt the electrical line. For example, in some embodiments, a plurality of electrical lines can be arranged to provide a fuse bank. Selective destruction of the electrical lines can be performed by using the above-described techniques so as to set selected fuses of the fuse bank. In particular, inkjet printing, selectively at locations determined, for example, as a result of measurements performed on the wafer, the substance onto the electrical lines, can selectively etch and thus destroy the electrical line to a achieve a “fuse blow” effect. In other words, a previously established electrical connection is removed. It should be understood that, in some embodiments, the techniques disclosed herein can also be used at a later stage to selectively re-establish the removed electrical connection. In a subsequent further inkjet printing step in accordance with the techniques disclosed herein, a blown fuse can be reset by further printing a conductive substance a the location of the blown fuse, i.e., a the location of the opening 435. Meanwhile, in the illustrated example, the second substance having become solid, the second substance forms an element 461 that, being formed by a wall of the second opening in the mask layer 420, has a sheer sidewall 465.

It should be understood that the techniques disclosed herein can be applied at any stage of manufacturing the semiconductor device. For example, the substrate 210, 310, 410 can be an unfinished product that includes a semiconductor device structure, complete or incomplete. Further processing steps such as those described above with reference to the figures may be needed to complete the semiconductor device structure so as to obtain a finished die that includes the semiconductor device in working order.

It should also be understood that the schematically illustrated examples that are described above can be unfinished. Thus, having performed method steps in accordance with the present disclosure, performance of further steps may be needed in order to obtain a finished semiconductor device product that is fully functional.

While the techniques disclosed above are described with respect to electrical elements including conductive and/or dielectric materials, these techniques can also be used in order to form elements that fulfil a mechanical function such as enhancing the substrate's resistance to mechanical stress, for example, by way of distributing and/or absorbing or otherwise mitigating the mechanical stress.

In some embodiments, the techniques described herein are used to form an alignment marker. A mask can be used to provide a pattern of cavities in the mask. Substance that is deposited in the cavities of the pattern can form the alignment marker for use in a subsequent alignment step after removal of the mask.

In some embodiments, the techniques described herein are used to selectively cover individual circuit elements or other portions of a semiconductor device structure manufactured on the substrate. As described in the example provided above with reference to process steps S130 and S150, in some embodiments, one mask layer can be used for selectively depositing one or more substances at one or more locations of the substrate.

Where a first substance and a second substance are deposited, selectively, at a same location on the substrate, one may functionally relate to the other. For example, the second substance can be dielectric while the first can be conductive, and the dielectric functions as an insulator that electrically isolates the conductive substance. In some embodiments, the second substance can react with the first substance. For example, a third layer can thus be formed that is sandwiched between the first substance and the second substance and, being a product of a chemical reaction of the second substance with the first substance, differs from both the first substance and the second substance.

At least one effect of the techniques disclosed herein can be that a result of a conventional process can be attained without using the conventional process. Further, substances can selectively be deposited to provide functionality and or information on the wafer that may be based on information related to the wafer in the manufacturing process itself. For example, a digital representation of a measured physical property can be coded into a fuse bank, i.e., a group of circuit elements selectively made, for example, conductive and non-conductive by an embodiment of the techniques disclosed herein.

In some embodiments, the techniques disclosed herein are used to form a micro-electro-mechanical element. In particular, the hardening of the selectively provided substance can be controlled so as to achieve a predetermined mechanical property of the resultant structure such as a predetermined elasticity.

It should be understood that the techniques disclosed herein can be used to provide a plurality of openings in the mask in a predetermined pattern and selectively apply substance to selected ones of the openings. As a result, a sub-pattern of substance can be formed. The sub-pattern can be used to represent coded information. For example, the sub-pattern can be a bar code pattern or a so-called QR code pattern.

Other embodiments include one or more semiconductor tools or semiconductor processing equipment configured to perform embodiments of the method steps disclosed herein.

As used herein, the wording ‘selectively’ means other than globally across a large portion or all of the wafer. Accordingly, selectively providing the substance on the wafer implies a target location or area ‘selected’ for delivery of the substance on the wafer that is less than the complete wafer.

As used herein, the wording ‘substance’ refers to a substance delivered to the wafer by using one of the printing techniques disclosed herein, in particular by an inkjet technique, a micro-aerosol printing technique or a micro-extrusion printing technique. Accordingly, the substance can also be referred to as ‘ink-substance’.

As used herein, the wording ‘semiconductor device structure’ can relate to a semiconductor device in a finished wafer. The term also encompasses a portion of a semiconductor device that is completed in a manufacturing process, while the manufacturing process is not yet completed, that is, manufacturing of the wafer is not yet completed. In other words, the semiconductor device structure can also denote a semiconductor device under construction and, hence, not necessarily a finished semiconductor device.

As used herein, the word ‘exemplary’ means serving as an embodiment, example, instance, or illustration. Any aspect or design described herein as ‘exemplary’ is not necessarily to be construed as preferred or advantageous over other aspects or designs. Rather, use of the word exemplary is intended to present concepts and techniques in a concrete fashion. The term ‘techniques’ may refer to one or more devices, apparatuses, systems, methods, articles of manufacture, and/or computer-readable instructions as indicated by the context described herein.

As used herein, the term ‘or’ is intended to mean an inclusive ‘or’ rather than an exclusive ‘or.’ That is, unless specified otherwise or clear from context, ‘X employs A or B’ is intended to mean any of the natural inclusive permutations. That is, if X employs A; X employs B; or X employs both A and B, then ‘X employs A or B’ is satisfied under any of the foregoing instances.

As used herein, the articles ‘a’ and ‘an’ should generally be construed to mean ‘one or more,’ unless specified otherwise or clear from context to be directed to a singular form.

As used herein, directional terminology, such as ‘top’, ‘bottom’, ‘front’, ‘back’, ‘leading’, ‘trailing’, etc., is used with reference to the orientation of the figure(s) being described. As used herein, terms such as ‘first’, ‘second’, and the like, are also used to describe various elements, regions, sections, etc. and are also not intended to be limiting.

The embodiments herein are described in terms of exemplary embodiments. However, it should be appreciated that individual aspects of the embodiments may be separately claimed and one or more of the features of the various embodiments may be combined. Thus, it is to be understood that the features of the various embodiments described herein may be combined with each other, unless specifically noted otherwise. The order in which the embodiments, methods and processes are described is not intended to be construed as limiting, and any number of the described embodiments, methods and processes may be combined. In some instances, well-known features are omitted or simplified to clarify the description of the exemplary embodiments. It is intended that this invention be limited only by the claims and the equivalents thereof.

What is claimed is:

1. A method, comprising:
providing a structured layer on a wafer; and
selectively providing a substance on a selected portion of the structured layer.

2. The method of claim 1, wherein the structured layer comprises a mask layer selected from a group consisting of a positive resist mask, a negative resist mask, an oxide mask and a nitride mask.

3. The method of claim 1, further comprising removing the structured layer from the wafer substrate.

4. The method of claim 1, wherein the substance, at the time of providing the substance, comprises the substance selected from a group consisting of a liquid, a suspension in a liquid, a paste, and any combination or derivative of these substances.

5. The method of claim 1, wherein the substance comprises a metal.

6. The method of claim 1, further comprising sintering the substance.

7. The method of claim 1, further comprising hardening the substance.

8. The method of claim 7, wherein hardening the substance comprises curing the substance.

9. The method of claim 1, further comprising cross-linking the substance.

10. The method of claim 1, further comprising using the substance to complement a circuit element structure at the selected portion of the wafer.

11. The method of claim 10, wherein the wafer comprises a plurality of semiconductor device structures and the circuit element structure forms part of one of the plurality of semiconductor device structures.

12. The method of claim 10, wherein the circuit element structure forms part of a wafer test circuit structure.

13. The method of claim 1, wherein selectively providing the substance comprises passivating a circuit element with the substance at the selected portion of the structured layer.

14. The method of claim 1, wherein the substance comprises an ink, and wherein selectively providing the substance comprises inkjet printing the ink onto the selected portion of the wafer.

15. The method of claim 1, wherein selectively providing the substance on the selected portion of the wafer comprises encoding information on the wafer.

16. The method of claim 11, wherein the plurality of semiconductor device structures form a portion of a corresponding plurality of integrated circuits.

17. A die comprising:
a semiconductor device on a substrate, wherein the semiconductor device includes a substance, and wherein the substance has a sidewall that is sheer with respect to one or more of a base surface or a top surface of the substrate.

18. The die of claim 17, wherein the substance is conductive and configures an element of the semiconductor device.

19. The die of claim 18, wherein the element comprises a constructive fuse element.

20. The die of claim 19, wherein the semiconductor device comprises a plurality of fuse elements arranged in a fuse bank including the constructive fuse element.

21. The die of claim 18, wherein the conductive substance is covered by a dielectric substance.
